(19) United States
(12) Patent Application Publication
(10) Pub. No.: US 2013/0345995 A1
(43) Pub. Date: Dec. 26, 2013

(54) Air Flow Control And Power Usage Of An Indoor Blower In An HVAC System

(71) Applicant: Carrier Corporation, Farmington, CT (US)

(72) Inventors: Rajendra K. Shah, Indianapolis, IN (US); Eugene Louis Mills, JR., Avon, IN (US)

(21) Appl. No.: 13/897,787

(22) Filed: May 20, 2013

Related U.S. Application Data
(60) Provisional application No. 61/649,500, filed on May 21, 2012.

(51) Int. Cl. G01F 1/05; G01R 21/133; G01F 1/34

(52) U.S. Cl. CPC G01F 1/05; G01F 1/34; G01R 21/133
USPC 702/47; 702/45; 702/61

(57) ABSTRACT

A method for determining an air flow of an air handler including an indoor blower and a motor coupled to a heating, ventilation, and cooling (HVAC) system, includes receiving a signal indicative of an air flow at an extreme operating range of the HVAC system; receiving operational constants of the air handler, the operational constants representing performance characteristics of the air handler; transmitting a torque command to the motor; receiving a motor signal indicative of an operating speed of the motor; and determining the air flow using at least the operating speed and the operational constants.

### CROSS REFERENCE TO RELATED APPLICATIONS

This application claims the benefit of U.S. provisional patent application Ser. No. 61/649,500 filed May 21, 2012, the entire contents of which are incorporated herein by reference.

### FIELD OF INVENTION

Embodiments relate generally to air flow control in an HVAC system and, more particularly, to a system and method for improved air flow control algorithms in an indoor air handling unit of a ducted HVAC system that provides more accurate air flow control over the full operating range of the air handler and potentially eliminates external measurement of the air flow for commissioning or diagnosis. Embodiments include a method for computing the power usage of an indoor blower motor without utilizing external power measuring devices and for calculating the external static pressure in the ducts attached to the air handling unit without any pressure measuring device.

### DESCRIPTION OF RELATED ART

Modern structures, such as office buildings and residences, utilize heating, ventilation, and cooling (HVAC) systems having controllers that allow users to control the environmental conditions within these structures. These controllers have evolved over time from simple temperature based controllers to more advanced programmable controllers, which allow users to program a schedule of temperature set points in one or more environmental control zones for a fixed number of time periods as well as to control the humidity in the control zones, or other similar conditions. Typically, these HVAC systems use an air handler connected to ducts to delivered conditioned air to an interior space. These ducts provide a path for air to be drawn from the conditioned space and then returned to the air handler. These duct systems vary in shape, cross section and length to serve the design constraints of a structure. The air handler includes a motor and a fan to move the air through the ducts, conditioning equipment and the space. These air handlers are designed to accommodate the wide range of loading represented by the various duct system designs used in these modern structures.

Some current air handlers use electronically commutated motors (ECM) with internal compensation algorithms that improve the blower system performance over induction motor driven models. The algorithms in these ECM driven blowers are capable of varying power output to provide improved blower performance to meet loading requirements over most of the air handler's operating envelope of mass flow versus static pressure loading. But, these current algorithms are incapable of accurately controlling the blowers to deliver the desired air volume flow rate or mass flow rate at the extremes of the air handler's operating range. Further, when operated outside the air handler's operating range, the delivered air flow is substantially different from the desired air flow and, because the operating point of the blower motor is unknown, the exact delivered flow is unpredictable.

### BRIEF SUMMARY

According to one aspect of the invention, a method for determining an air flow of an air handler including an indoor blower and a motor coupled to a heating, ventilation, and cooling (HVAC) system, includes receiving a signal indicative of an air flow at an extreme operating range of the HVAC system; receiving operational constants of the air handler, the operational constants representing performance characteristics of the air handler; transmitting a torque command to the motor; receiving a motor signal indicative of an operating speed of the motor; and determining the air flow using at least the operating speed and the operational constants.

According to another aspect of the invention, a method for determining power consumption of a motor coupled to an indoor blower of an air handler for a heating, ventilation, and cooling (HVAC) system, includes receiving a signal indicative of an air flow; receiving operational constants of the air handler, the operational constants representing performance characteristics of the air handler; transmitting a torque command to the motor; receiving a motor signal indicative of an operating speed of the motor; and determining the power consumption of the motor at the operating speed.

According to another aspect of the invention, a method for determining external static pressure in a duct of an air handler including an indoor blower and a motor coupled to a heating, ventilation, and cooling (HVAC) system, includes receiving a signal indicative of an air flow at an extreme operating range of the HVAC system; receiving operational constants of the air handler, the operational constants representing performance characteristics of the air handler; transmitting a torque command to the motor; receiving a motor signal indicative of an operating speed of the motor; and determining the external static pressure using at least the operating speed and the operational constants.

Other aspects, features, and techniques of the invention will become more apparent from the following description taken in conjunction with the drawings.

### BRIEF DESCRIPTION OF THE SEVERAL VIEWS OF THE DRAWINGS

Referring now to the drawings wherein like elements are numbered alike in the FIGURES:

FIG. 1 illustrates a schematic view of an HVAC system including a system control unit, and an air handler control unit, either of which may be used for implementing aspects of internal compensation algorithms according to an embodiment of the invention;

FIG. 2 is a flow diagram illustrating a method for predicting operating parameters of the HVAC system shown in FIG. 1 according to an embodiment of the invention; and

FIG. 3 illustrates a pressure coefficient ψ plotted against a flow coefficient φ and a power coefficient λ0 plotted against the flow coefficient φ.

### DETAILED DESCRIPTION

Embodiments of an HVAC system include an air handler control unit for implementing an internal compensation algorithm that determines operating parameters for an air handler system according to physics of an air handler blower. The air handler control unit provides more accurate control of the blower through its entire intended range of operation. The algorithm is used to determine the air handler system operating parameters of indoor air flow volume, indoor air mass flow, external static pressure in the duct system, and blower motor power consumption, including power consumption at altitudes. Specifically the air flow is controlled and delivered to the current needs of the system operating mode, while the external static pressure and blower motor power are determined and displayed to the installing or service technician. The accurate determination of these parameters eliminates the need for field measurement for commissioning or diagnosis.

It should be noted that in a typical ducted residential HVAC system, the air handler refers to the indoor air handling unit that delivers conditioned air through air ducts to various parts of the home. In one typical system type, the indoor air handler is also referred to as the Fan Coil Unit and includes an indoor blower and motor as well as indoor refrigerant coil to provide cooling or heating in conjunction with an outside air conditioner or heat pump unit. The Fan Coil Unit may also optionally include a supplemental heat source such as an electric strip heater or a hydronic hot water coil. In another typical system, the indoor air handler includes a Gas Furnace Unit that also includes an indoor blower and motor, which is capable of delivering heat by combusting a fuel such as natural gas or propane. Embodiments apply to both types of air handler units and are directed to air delivery capabilities, the power consumption of the blower motor and the duct restriction represented by the external static pressure.

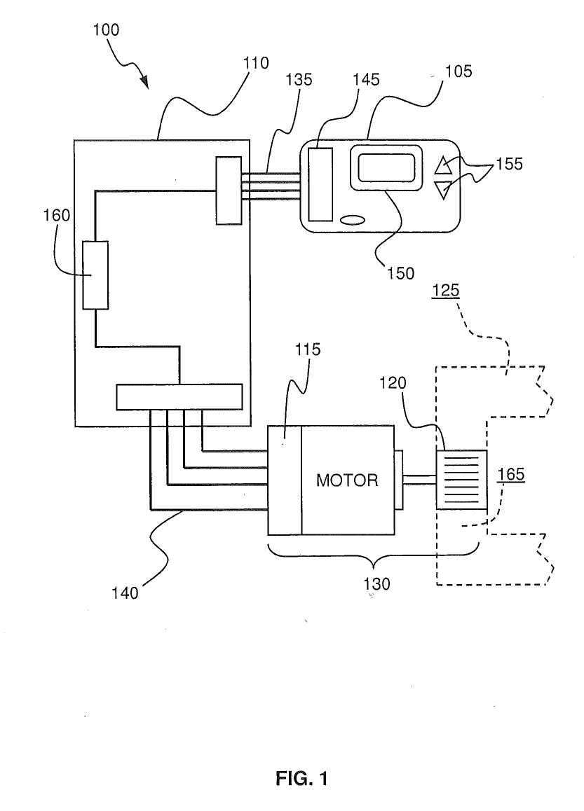

Referring now to the drawings, FIG. 1 illustrates a schematic view of an HVAC system 100. Particularly, the HVAC system 100 includes a system control unit 105, an air handler controller 110, and a blower system 130 (as part of an air handler) having a variable speed motor 115 and a centrifugal blower 120 connected to the duct system 125. The system control unit 105 is in operative communication with the air handler controller 110 over system communication bus 135, which communicates signals between the system control unit 105 and the air handler controller 110. As a result of the bi-directional flow of information between the system control unit 105 and the air handler controller 110, the algorithms described in exemplary embodiments may be implemented in either control unit 105 or controller 110. Also, in some embodiments, certain aspects of the algorithms may be implemented in control unit 105 while other aspects may be implemented in controller 110.

In one embodiment, the system control unit 105 includes a computing system 145 having a computer program stored on nonvolatile memory to execute instructions via a microprocessor related to aspects of an air flow rate algorithm to determine the predicted operating parameters of air volume flow, air mass flow, external static pressure load, and operating power consumption of the blower 120 in HVAC system 100. In embodiments, the microprocessor may be any type of processor (CPU), including a general purpose processor, a digital signal processor, a microcontroller, an application specific integrated circuit, a field programmable gate array, or the like. The system control unit 105 includes a user interface element 150 such as, for example, a graphic user interface (GUI), a CRT display, a LCD display, or other similar type of interface by which a user of the HVAC system 100 may be provided with system status and/or the determined operating parameters of the air handler. Also, the system control unit 105 includes a user input element 155 by which a user may change the desired operating characteristics of the HVAC system 100, such as air flow requirements. The user may also enter certain specific aspects of the air handler installation such as, for example, the local altitude for operation of the air handler, which may be used in the various algorithms. It is to be appreciated that the system control unit 105 implements aspects of an air flow control algorithm for determining, in an embodiment, the operating parameters including air volume flow rate or air mass flow rate, the blower 120 power consumption, and duct static pressure at the extremes of the operating range of the motor 115 (e.g., at or near maximum motor RPM). The determination of these operating parameters through the algorithms eliminates a need to measure these parameters against published parameters, thereby providing for self-certification of the air handler and diagnosis of the HVAC system 100. The determined operating parameters may be compared to published, expected parameters to provide a certification that the air handler meets the published parameters. It should be appreciated that while aspects of the algorithms described above may be executed in the air handler controller 110, in other embodiments, any of the above algorithms may also be executed in the system control unit 105 without departing from the scope of the invention

Also shown, HVAC system 100 includes an air handler controller 110 operably connected to the blower system 130 for transmitting torque commands to the blower system 130. The air handler controller 110 includes a processor 160 and memory, which stores operational characteristics of blower system 130 that are specific to the air handler unit model being used. In some non-limiting embodiments, the operational characteristics include blower diameter and blower operating torque. In one embodiment, air handler controller 110 transmits, over the motor communication bus 140, operation requests to the variable speed motor 115 in the form of a torque command, and receives operating speed of the motor 115 via the motor communication bus 140. The variable speed motor 115 receives operational torque commands from the air handler controller 110 and impels blades of the blower 120 at the commanded motor operating torque. In an embodiment, the computing system 160 of the air handler controller 110 implements one or more algorithms for determining the air volume flow rate, air mass flow rate, the static pressure in the duct system 125 over the full range of duct restrictions and air flow range, and operating power consumption by the blower system 130 based on the specific characteristic constants of the air handler unit including characteristics of the specific motor 115 and blower 120 being used.

In an embodiment for an operating mode of the HVAC system 100, the system control unit 105 communicates to the air handler controller 110 a command for a desired indoor air flow. The desired indoor air flow depends on user settings such as, for example, the current operating mode, such as heating, cooling, dehumidification, humidification, circulation fan, outside fresh air intake etc., the number of stages of heating or cooling, and other factors. In some other operating modes, such as gas heating or electric heating, the system control unit 105 commands the stages of heat and the air handler controller determines the corresponding desired indoor air flow. Also, the air handler controller 110 is in direct communication with the blower system 130 over motor communication bus 140, which serves to transmit, in one embodiment, torque commands from the air handler controller 110 to the blower system 130 and receive operation feedback from the blower system 130 such as, for example, the operating speed of the motor 115.

In an embodiment, an algorithm for determining air flow control as well as determining the external static pressure and blower motor power consumption reside in the memory of the air handler controller 110 that are executed by the processor of the controller 110. Further, for every air handler unit model it is intended to control, the air handler controller 110 stores a full set of characteristic constants used by the above algorithms. These characteristic constants are pre-determined for each air handler model by characterizing tests run during the product development process for each model. Also, during the manufacturing process, the information about the specific air handler unit model is also stored in the memory of the air handler controller unit 110. In one embodiment, when the air handler controller 110 is a field service replacement part that has not gone through the air handler unit's manufacturing process, the service technician may need to enter the specific air handler unit model information into the system control unit 105 at the time of the field replacement. The system control unit 105 then communicates the specific air handler model information to the air handler controller 110. Knowing the specific air handler unit model, the air handler controller 110 looks up the specific characteristic constants applicable to the model from the list of constants for all possible models stored in its memory. These characteristic constants can then be used in the execution of the algorithms

In an embodiment, the air handler controller 110 executes an air flow control algorithm that resides within memory of the air handler controller 110 for computing torque command values for the motor 115. The air handler controller 110 may receive a commanded desired air flow from the system control unit 105 over the system communication bus 135. In some operating modes, the air handler controller 110 may determine the desired air flow without interfacing with the system control unit 105. The air handler controller 110 sends an initial torque command to the blower motor 115 over the motor communication bus 140. The motor operates the blower at the commanded torque and, after a short stabilization period, reports back the operating speed of motor 115 to the air handler controller 110 over the bus 140. The air flow control algorithm uses the desired air flow, the reported motor speed, air handler characteristic constants and density adjustments for altitude to compute a new torque command value to be transmitted to the motor 115. Operation of the motor 115 at this commanded torque level ensures the delivery of the desired air flow. This process is repeated periodically with updated values of desired air flow and motor speed.

Further, in an embodiment, the air handler controller 110 executes an air flow control algorithm for determining the external static pressure in the duct system 125 that is external to the air handler unit. The algorithm determines the external static pressure based on the desired air flow command, the reported motor speed, altitude based density adjustments and another set of characteristic constants specific to the air handler unit being controlled. Alternatively, with a different set of air handler characteristic constants, the external static pressure may be computed based on commanded motor torque, reported motor speed and altitude based density adjustments. This computation is repeated periodically with the updated values of air flow or torque and speed.

In another embodiment, the air handler controller 110 executes aspects of an air flow control algorithm for determining blower motor 115 power consumption. The air flow control algorithm determines the blower motor 115 power consumption based on the desired air flow command, the reported motor speed, altitude based density adjustments and other set of characteristic constants specific to the air handler unit being controlled. Alternatively, with a different set of air handler characteristic constants, the blower motor 115 power may be computed based on commanded motor torque, reported motor speed and altitude based density adjustments. This computation is repeated periodically with the updated values of air flow or torque and speed.

In an embodiment, the algorithms may utilize computational formulas for determining operating parameters, although, in other embodiments, several different computational formulas may be used. In one embodiment, the method of calculating the static pressure begins with the use of performance parameters for fan systems. These parameters are used to predict fan and blower performance, and form the basis for the widely accepted “fan laws.” The parameters used are:

Flow Coefficient: φ=700.332(Q/NbD²); (1)

Pressure Coefficient: ψ=1.7845×10⁷(Pₛ/ρN²D²); (2)

Power Coefficient: λ=1.9528×10¹³(BHP/ρN³bD⁴). (3)

Where:

Q=the system volume airflow rate (ft³/min or cfm);

b=the blower length (inches);

D=the blower diameter (inches);

N=the blower speed (revolutions/min or rpm);

ρ=the density of the air or “air density” (lb/ft³);

Pₛ=the system total or external static pressure (inches water column);

BHP=the fan output horsepower.

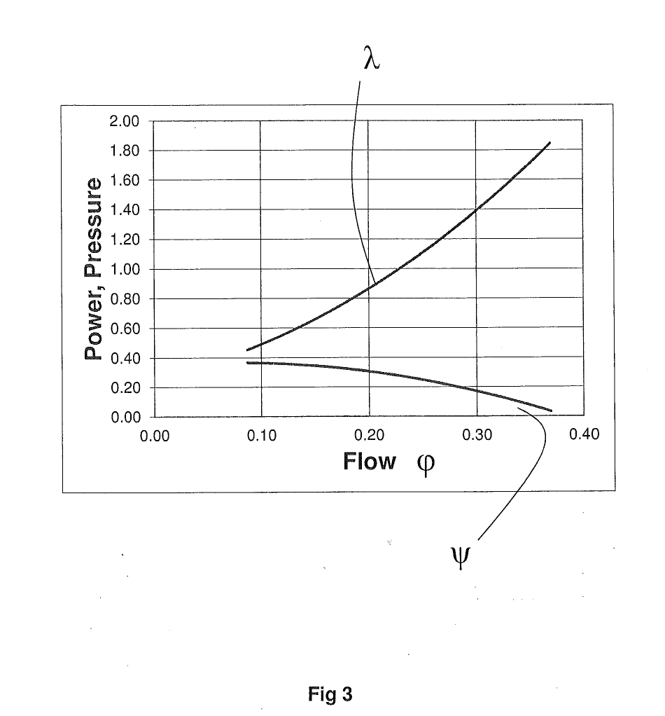

The Pressure Coefficient ψ plotted against the Flow Coefficient φ describes the blower pressure performance and can be used to predict the static pressure developed at any operating condition of N, Q and ρ. The power coefficient λ plotted against the Flow Coefficient φ describes the blower power performance and can be used to predict or control a communicating blower motor to the shaft power required at any Q desired, pressure load Pₛ and air density ρ. FIG. 3 illustrates the Pressure Coefficient ψ plotted against the Flow Coefficient φ and the power coefficient λ plotted against the Flow Coefficient φ.

The Flow-Pressure and Flow-Power relationships are determined using air-flow performance tables (describing N, Q, and power vs. static pressure), which are experimentally measured for any given HVAC installation using, for example, the procedures and apparatus described in ASHRAE (American Society of Heating, Refrigerating, and Air-Conditioning Engineers, Inc.) Standard 37, Methods of Testing for Rating Unitary Air-Conditioning and Heat Pump Equipment, the disclosure of which is incorporated by reference herein. The Flow, Pressure and Power Coefficients are calculated using equations (1), (2), and (3) and the Pressure and Power Coefficients are regressed against the Flow Coefficient. The result is polynomials whose coefficients are the empirically determined pressure and power equation coefficients. While the example provided herein is shown as a third order polynomial, it is to be appreciated that higher order polynomials may be generated should greater accuracy be desired.

ψ=p₃φ³+p₂φ²+p₁φ+p₀; (4)

λ=l₃φ³+l₂φ²+l₁φ+l₀ (5)

Substituting the right hand side of equation (1) for in equations (4) and (5), then substituting the right side of equation (2) for ψ in equation (4), and substituting the right side of equation (3) for λ in equation (5), equations (4) and (5) may be mathematically reduced to a universal mathematical model which may be used to describe any air handler system. Solving for the static pressure term Pₛ yields the desired pressure model:

Pₛ=j₃*Q³/N+j₂*Q²+j₁*Q*N+j₀*N²+P₀; (6)

j₃=19.5336*p₃*ρ/(b²*D⁴); (7)

j₂=2.7891*10⁻²*p₂*ρ/(b²*D²); (8)

j₁=3.9826*10⁻⁵*p₁*ρ/b; (9)

j₀=p₀*ρ*D²/1.7584*10⁷ (10)

Solving for the Power term yields the desired Torque Model:

T=k₃*Q³/N+k₂*Q²+k₁*Q*N+k₀*N²+T₀; (11)

k₃=(1.4781*l₃*ρ)/(b²*D²); (12)

k₂=(2.1106*10⁻³*l₂ρ)/b; (13)

k₁=3.0137*10⁻⁶*l₁*ρ*D²; (14)

k₀=(l₀*ρ*D⁴*b)/(2.3238*10⁸) (15)

Where:
Pₛ is the system total or external static pressure (inches water column);
T is the blower shaft torque;
Q is the system volume airflow rate (ft³/min or cfm);
N is the blower speed (revolutions/min or rpm);
ρ is the density of the air (lb/ft³);
D is the blower diameter (inches);
p₃, p₂, p₁, p₀, l₃, l₂, l₁, and l₀ are the empirically determined pressure and torque equation coefficients;
j₃, j₂, j₁, j₀ are stored system pressure coefficients;
k₃, k₂, k₁, k₀ are stored system power coefficients;
P₀ is a pressure offset that improves model correlation with data; and
T₀ is a torque offset that improves model correlation with data.

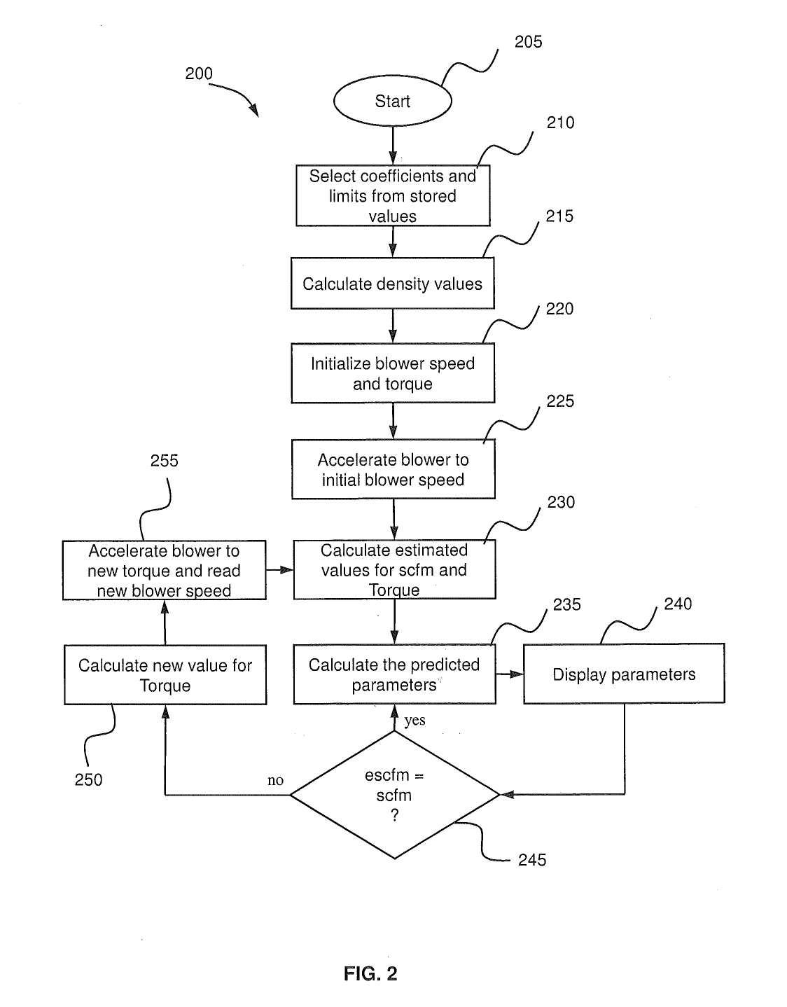

In operation, this model is stored as a series of instructions in memory of system control unit 105 and used by the computer system 145 to use the stored system pressure coefficients (j₃, j₂, j₁, j₀), the system power coefficients (k₃, k₂, k₁, k₀), and the model offsets (P₀ and T₀), the disclosed pressure model (equation 6) and torque model (equation 11) to control an air handler blower to deliver a prescribed air mass flow rate, read the blower speed and air density information, and use the pressure and torque models to calculate and display the duct system static pressure, the blower speed and power consumption, the air volume flow rate (cfm) and the air mass flow rate (scfm), as described with reference to FIG. 2. The torque model represents torque, T, as a function of blower speed, N, raised to a power n, where n is greater than 1. It is to be appreciated that the model uses stored data to predict blower performance. The model is efficiently implemented in a low cost system control unit 105 that accurately and automatically provides the blower speed and power consumption, air volume flow rate, air mass flow rate, and duct static pressure loading through the entire intended range of blower operation without the addition of externally applied measurement devices.

Referring now to FIG. 2, there is shown a flow diagram illustrating a process 200 for calculating the power consumption (W) of blower system 130, duct 125 static pressure (Pₛ), air mass flow rate (scfm) and air volume flow rate (cfm) from an operating torque of motor 115 according to an embodiment of the invention. The process 200 is initiated in 205, and in 210, stored coefficients and limits are selected by system control unit 105. Particularly, memory of control unit 105 stores the altitude in increments of 200 ft, stores system pressure coefficients (j₃, j₂, j₁, j₀), stores system power coefficients (k₃, k₂, k₁, k₀), stores model offsets (P₀ and T₀), stores standby power of the motor (P_{standby}), and stores motor efficiency coefficients (m₀, m₁, m₂, m₃, ₘ₄, m₅, m₆, m₇, m₈, m₉, and m₁₀), and selects these for processing by computing system 145. Temperature (T_{f}) is measured at the blower inlet 165 (FIG. 1) of blower 120 through a temperature sensor (not shown). In 215, the density ratio (dr) is calculated from the altitude pressure ratio (pr) for a particular elevation according to equations 16 and 18.

Altitude pressure ratio (pr)=[1.0−(elevation/145442)]^{5.255876}; (16)

Altitude barometer estimated (BAR_{estimated})=29.921*pr; (17)

Density ratio (dr)=BAR_{estimated}/[0.05665*(T_{f}+459.7)]. (18)

In 220, the air handler controller 110 receives a requested scfm demand from the system control unit 105 and initializes speed (Nᵢ) and torque (Tᵢ) of the blower 120 according to the following equations:

Assume an initial static pressure Pᵢ (inches water column)

Initial speed Nᵢ=[−b+(b²−4*a*c)^{0.5}]/(2*a); (19)

Where:

a=j₀; (20)

b=j₁*scfm; (21)

c=j₂*scfm²−Pᵢ+P₀; (22)

Initial torque Tᵢ=k₂*scfm²+k₁*scfm*Nᵢ+k₀*Nᵢ²; (23)

In 225, the air handler controller 110 accelerates the blower 120 to Ni by setting motor torque to Ti, and in 230, the system control unit 105 stores reads the motor speed N_{R} (rpm) and motor torque T_{R} from the motor 115 and calculates the estimated air mass flow rate (escfm) and a new operating torque (T_{operating}) according to the following equations:

escfm=[−e+(e²−4*d*f)^{0.5}]/(2*d); (24)

T_{operating}=(k₂*scfm²+k₁*scfm*N_{R}+k₀*N_{R}²+T₀; (25)

Where:

d=k₂; (26)

e=k₁*N_{R}; (27)

f=k₀*N_{R}²−T_{R}+T₀; (28)

In 235, the system control unit 105 calculates the air volume flow rate (cfm), air mass flow rate (scfm), duct static pressure (Pₛ), and Power consumption (W) according to the following equations:

cfm=escfm/dr; (29)

Pₛ=(j₂*cfm²+j₁*cfm*N_{R}+j₀*N_{R}²+P₀); (30)

Pₒᵤₜ=N_{R}*T_{operating}*max motor torque*0.008875; (31)

η=m₀+m₁*T_{operating}+m₂*T_{operating}²+m₃*T_{operating}³+m₄*T_{operating}⁴+m₅*T_{operating}⁵+m₆*N_{R}+m₇*N_{R}²+M₈*N_{R}³+m₉*N_{R}⁴+m₁₀*N_{R}⁵; (32)

Power (W)=Pₒᵤₜ/η+P_{standby}; (33),
where P_{standby} is a power value read as a part of the design experimentation and stored as a blower parameter.

In 240, the power consumption (W) of blower system 130, duct 125 static pressure (Pₛ), air mass flow rate (scfm) and air volume flow rate (cfm) are displayed on user interface element 150. In 245 estimated air mass flow rate is compared to the air mass flow rate. If these values are equal, flow proceeds to 235. If the estimated air mass flow rate does not equal the air mass flow rate then flow proceeds to 250 where a new value is calculated for the torque. At 255, the blower is accelerated to the new torque and the new blower speed is read. The process then continues to 230 as described above.

It should be noted that two exemplary air flow control methods have been provided to calculate the new value for torque required to deliver the requested air mass flow rate (scfm). The first method is in FIG. 2, 230, equation 25, where the new torque value is directly calculated from the requested air mass flow rate (scfm), the motor speed N_{R}, and the coefficients. This calculation is repeated periodically and results in the delivered air mass flow rate equal to the requested air mass flow rate (scfm). In this method, the calculated torque value periodically adjusts to duct static pressure load changes indicated by changes in motor speed as well as to changes in the requested air mass flow rate. Alternatively, a second air flow control method is illustrated in the flow chart of FIG. 2. In this second method, in 230, an estimated air mass flow rate (escfm) is first calculated per equation 24. This estimated air mass flow rate is then compared to the requested air mass flow rate (scfm), and, in 250, a new value of torque is calculated based on this difference. Again this process is repeated until the estimated air mass flow rate (escfm) matches the requested air mass flow rate (scfm).

An aspect of the invention is to accurately deliver a wide range of requested air flow rates over a wide range of duct static pressures, including extremes on the high and low side. The methods described here, including the methods for calculating torque to achieve a requested air flow rate, result in accurate air flow control over the full operating range of the blower motor 115, referring again to FIG. 1. The operating range of blower motor 115 is characterized by its horsepower rating, which in turn, limits the highest torque and speed it can deliver. For example, the motor 115 can deliver a certain torque value up to a certain speed, beyond which the torque starts dropping off. In extreme cases, a highly restrictive duct system 125 can push the speed of the blower motor 115 outside its operating range, such that the motor 115 is incapable of achieving the calculated torque value and, consequently, the requested air mass flow rate. Even when the requested air mass flow rate cannot be achieved, embodiments deliver as much air flow as possible and display to the service technician the exact air flow being delivered, for example on the user interface 150. The following are exemplary methods to achieve this.

In some systems, the blower motor 115 is capable of sending a signal indicating the speed-torque out of range condition to the air handler control 110 over the motor communication bus 140. This information can also be communicated to the system control 105 over the system communication bus 135. Alternatively, the speed-torque range capability of the blower motor 115 can be predetermined and stored in the memory (e.g. look-up table) of the air handler control. For example, the speed-torque range can be represented as the highest speed (speed limit) achievable for each torque value over the full operating range. The speed-torque range may be stored either as a table of torque and speed limit values or as a linear or non-linear equation relating the speed limit to the torque. The table or equations may be used to detect operation at an extreme range.

Referring back to FIG. 2, in 250 a new value of torque is calculated to achieve the requested air mass flow rate. In 255 the calculated torque command is sent to the blower motor and the resulting motor speed is read back from the motor, both over the motor communication bus. At this point, if the speed and torque combination falls outside the range of capability of the motor, the motor can send back an out of range signal over the motor communication bus. Alternatively, if the motor is incapable of sending an out of range signal, the air handler control can determine the out of range condition by comparing the actual speed and torque to the predetermined speed-torque range stored in its memory. In either case, in response to the out of range condition, the air flow control algorithm reduces the requested air mass flow rate by a certain amount, re-calculates a new torque, sends the torque command to the motor and reads back the new speed. The air mass flow rate reduction is repeated until the speed and the torque fall within the operating range of the motor. At this point, the air mass flow rate, though less than the requested value, is accurately known, and may be displayed to the service technician. In this manner, the air mass flow rate is always accurately known, even in duct systems with extreme restriction levels. In addition, since the operation of the blower motor is always maintained within its operating range, in 235 the calculation of the other parameters, power consumption (W) and duct static pressure (Pₛ), is also accurate.

The technical effects and benefits of embodiments relate to an HVAC system include an air handler control unit for implementing an internal compensation algorithm to determine operating parameters for an air handler system. The algorithm is used to determine the air handler system operating parameters of indoor air flow volume, indoor air mass flow, external static pressure in a duct system, and blower motor power consumption, including consumption at altitudes. An accurate determination of these parameters eliminates the need for field measurement required for commissioning or diagnosis.

The terminology used herein is for the purpose of describing particular embodiments only and is not intended to be limiting of the invention. While the description of the present invention has been presented for purposes of illustration and description, it is not intended to be exhaustive or limited to the invention in the form disclosed. Many modifications, variations, alterations, substitutions, or equivalent arrangement not hereto described will be apparent to those of ordinary skill in the art without departing from the scope and spirit of the invention. Additionally, while the various embodiments of the invention have been described, it is to be understood that aspects of the invention may include only some of the described embodiments. Accordingly, the invention is not to be seen as limited by the foregoing description, but is only limited by the scope of the appended claims.

1. A method for determining an air flow of an air handler including an indoor blower and a motor coupled to a heating, ventilation, and cooling (HVAC) system, comprising:
receiving a signal indicative of an air flow at an extreme operating range of the HVAC system;
receiving operational constants of the air handler, the operational constants representing performance characteristics of the air handler;
transmitting a torque command to the motor;
receiving a motor signal indicative of an operating speed of the motor; and
determining the air flow using at least the operating speed and the operational constants.

2. The method of claim 1, further comprising periodically transmitting additional torque commands to the motor in response to determining the air flow.

3. The method of claim 2, wherein the transmitting additional torque commands comprises comparing the air flow to an estimate air flow, and generating an additional torque command in response to a difference between the air flow and the estimated air flow.

4. The method of claim 1, wherein the operational constants include at least one of system pressure coefficients, system power coefficients, motor efficiency coefficients, pressure offset, and torque offset.

5.-8. (canceled)

9. The method of claim 1, further comprising determining the air flow at static pressure load changes.

10. The method of claim 1, further comprising determining system power coefficients using:
k₀=(l₀*ρ*D⁴*b)/(2.3238*10⁸)
k₁=3.0137*10⁻⁶*l₁*ρ*D²; and
k₂=(2.1106*10⁻³*l₂ρ)/b4;
where ρ is the density of air, l₀, l₁, l₂ are the demand coefficients, D is the blower diameter, and b is the blower length.

11.-14. (canceled)

15. A method for determining power consumption of a motor coupled to an indoor blower of an air handler for a heating, ventilation, and cooling (HVAC) system, comprising:
receiving a signal indicative of an air flow;
receiving operational constants of the air handler, the operational constants representing performance characteristics of the air handler;
transmitting a torque command to the motor;
receiving a motor signal indicative of an operating speed of the motor; and
determining the power consumption of the motor at the operating speed.

16. The method of claim 15, further comprising periodically transmitting additional torque commands to the motor in response to the determining of the power consumption.

17. The method of claim 15, wherein the operational constants include at least one of system pressure coefficients, system power coefficients, motor efficiency coefficients, pressure offset, and torque offset.

18.-21. (canceled)

22. The method of claim 15, further comprising determining the air flow rate at static pressure load changes.

23. The method of claim 15, further comprising determining system power coefficients using:
k₀=(l₀*ρ*D⁴*b)/(2.3238*10⁸)
k₁=3.0137*10⁻⁶*l₁*ρ*D²; and
k₂=(2.1106*10⁻³*l₂ρ)/b4;
where ρ is the density of air, l₀, l₁, l₂ are the demand coefficients, D is the blower diameter, and b is the blower length.

24.-25. (canceled)

26. A method for determining external static pressure in a duct of an air handler including an indoor blower and a motor coupled to a heating, ventilation, and cooling (HVAC) system, comprising:
receiving a signal indicative of an air flow at an extreme operating range of the HVAC system;
receiving operational constants of the air handler, the operational constants representing performance characteristics of the air handler.
transmitting a torque command to the motor;
receiving a motor signal indicative of an operating speed of the motor; and
determining the external static pressure using at least the operating speed and the operational constants.

27. The method of claim 26, wherein the operational constants include at least one of system pressure coefficients, system power coefficients, motor efficiency coefficients, pressure offset, and torque offset.

28.-31. (canceled)

32. The method of claim 26, further comprising determining the air flow at static pressure load changes.

33. The method of claim 26, further comprising determining system power coefficients using:
k₀=(l₀*ρ*D⁴*b)/(2.3238*10⁸)
k₁=3.0137*10⁻⁶*l₁*ρ*D²; and
k₂=(2.1106*10⁻³*l₂ρ)/b4;
where ρ is the density of air, l₀, l₁, l₂ are the Torque coefficients, D is the blower diameter, and b is the blower length.

34. The method of claim 26, further comprising determining the system pressure coefficients using:
j₀=p₀*ρ*D²/1.7584*10⁷;
j₁=3.9826*10⁻⁵*p₁*ρ/b;
j₂=2.7891*10⁻²*p₂*ρ/(b²*D²)
where ρ is the density of air, p₀, p₁, p₂ are the pressure coefficients, D is the blower diameter, and b is the blower length.

35.-38. (canceled)

39. A method for determining an air flow of an air handler including an indoor blower and a motor coupled to a heating, ventilation, and cooling (HVAC) system, comprising:
providing a torque model relating blower shaft torque to parameters of the HVAC system; and
applying the torque model during operation of the air handler to derive the air flow;
wherein the torque model represents torque, T, as a function of blower speed, N, raised to a power n, where n is greater than 1.

40. The method of claim 39, wherein n is equal to 2.

41. The method of claim 39, wherein the torque model is provided by:
T=k₃*Q³/N+k₂*Q²+k₁*Q*N+k₀*N²+T₀;
k₃=(1.4781*l₃*ρ)/(b²*D²);
k₂=(2.1106*10⁻³*l₂ρ)/b;
k₁=3.0137*10⁻⁶*l₁*ρ*D²;
k₀=(l₀*ρ*D⁴*b)/(2.3238*10⁸)
Where:
Pₛ is system total or external static pressure;
T is blower shaft torque;
Q is system volume airflow rate;
N is blower speed;
ρ is density of the air;
D is blower diameter;
p₃, p₂, p₁, p₀, l₃, l₂, l₁, and l₀ are pressure and torque equation coefficients;
j₃, j₂, j₁, j₀ are system pressure coefficients;
k₃, k₂, k₁, k₀ are system power coefficients;
P₀ is a pressure offset; and
T₀ is a torque offset.
